(19) United States
(12) Patent Application Publication
(10) Pub. No.: US 2007/0109746 A1
(43) Pub. Date: May 17, 2007

(54) Liquid cooling of electronic system and method

(76) Inventor: David A. Klein, Richardson, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/274,769

(22) Filed: Nov. 15, 2005

(51) Int. Cl. H05K 7/20

(52) U.S. Cl. 361/699; 165/80.4

(57) ABSTRACT

Various embodiments of a cooling system and method for disassembling a cooling system are provided. In one embodiment, a system is provided that comprises a closed circulation path containing liquid cooling medium, an impeller that is at least partially disposed within the closed circulation path, and a motor coupled to the impeller and disposed external to the closed circulation path. The system also includes an electronic system in thermal communication with the closed circulation path.

### BACKGROUND

In many electronic systems, the heat-generating components that process information remain cooled by air cooling systems. The heat that a heat-generating component such as a central processing unit (CPU), for example, generates increases as its data-processing speed rises and also as it performs more and more functions. For example, in order to generate new speeds, CPUs have more transistors and are drawing more power and have higher clock rates. Therefore, the trend in power requirements suggests that processor and memory power may require more cooling capacity than what can be provided by air cooling. Heat sinks, such as radiators, have been added to electronic systems to help alleviate some of the heat produced by the heat-generating components into the surrounding environment. A problem is that the size of radiators heat sinks and fans necessary to dissipate the heat within the housings of electronic systems present unworkable solutions.

Liquid cooling systems are known to provide an alternative to air cooling. In a liquid cooling system, a liquid cooling fluid which has a far higher specific heat than air is circulated inside the electronic system to dissipate heat. For example, the liquid cooling fluid can contact a portion of a heat-generating component or a heat sink to transfer heat from the higher temperature heat-generating component to the lower temperature liquid. The temperature of the liquid cooling fluid is elevated and transfers the heat to the ambient air and the temperature of the liquid cooling fluid is lowered again. The liquid cooling fluid then travels back through the system to the heat-generating component to continue the process. A problem, however, is that in many applications the risks involved in liquid cooling can be greater due to down-time in maintenance and repair and the possible damage caused by leaking liquid cooling fluid.

### BRIEF DESCRIPTION OF THE SEVERAL VIEWS OF THE DRAWINGS

The example embodiments of the present invention can be understood with reference to the following drawings. The components in the drawings are not necessarily to scale. Also, in the drawings, like reference numerals designate corresponding parts throughout the several views.

FIG. 1 is a perspective view of an electronic system having a liquid cooling system, according to an embodiment of the present invention;

FIG. 2 is a cross-sectional view of the electronic system of FIG. 1 along lines 2-2 showing a heat-generating component mounted to a printed circuit board and cooled by the liquid cooling system, according to an embodiment of the present invention;

FIG. 3 is a perspective view of the electronic system of FIG. 1 showing a liquid cooling system having a magnetically-driven impeller attachable to a circuit board, according to an embodiment of the present invention; and

FIG. 4 is a cut-away perspective view of a portion of an electronic system showing a liquid cooling system having a mechanically-driven impeller attachable to a circuit board, according to another embodiment of the present invention.

### DETAILED DESCRIPTION

For convenience, an electronic system in accordance with example embodiments of the present invention is described within the environment of a computer. However, one of ordinary skill in the art can appreciate that embodiments of the electronic system can be within the context of one of several electronic devices containing electrical components.

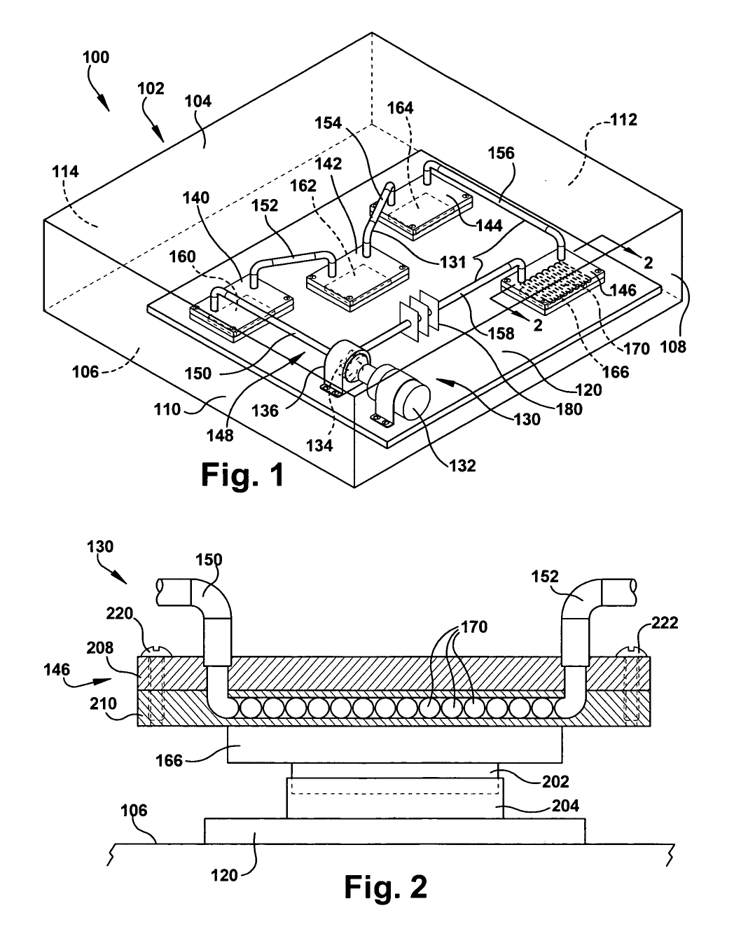

FIG. 1 shows a perspective view of an electronic system 100 according to an embodiment of the present invention. The electronic system 100 resides in an enclosure 102 having a top portion 104, a base portion 106, and side walls, for example, a front wall 108, left and right side walls 110, 112, and a back wall 114. The base portion 106 supports a circuit board 120 and a liquid cooling system 130 internal to the enclosure 102.

The liquid cooling system 130 includes a motor 132, an impeller 134 (shown in phantom) enclosed by impeller housing 136, a plurality of heat sinks 140, 142, 144, 146, and conduit 148 which carries the liquid cooling medium between heat sinks 140, 142, 144, and 146 for example, through conduit portions 150, 152, 154, 156, and 158. The conduit 148 can be for example, a continuous tubing that flows through and between the heat sinks 140, 142, 144, 146. In an alternative embodiment, portions of conduit 148, for example, portions 150, 152, 154, 156, and 158 can be formed by the heat sinks 140, 142, 144, 146, respectively.

A heat-generating component, such as heat-generating components 160, 162, 164, 166, which can be for example an integrated circuit or chip, can generate much heat as it operates to process data at high speeds to perform many functions. During operation the temperature of electronic system 100 becomes elevated and the environment needs to be cooled to ensure the stable operation of heat-generating components and other electrical components. Cooling is facilitated by the cooling system 130 having heat sinks 140, 142, 144, and 146.

In one embodiment the liquid cooling medium flows along a closed circulation path 131. At least a portion of the closed circulation path 131 of the liquid cooling system 130 contacts one or more heat sinks 140, 142, 144, and 146. In an alternative embodiment, the entire closed circulation path 131 can contact the heat sink. The electronic system 100 of FIG. 1 has a plurality of heat sinks such as heat sinks 140, 142, 144, and 146, however, the electronic system 100 can have a single heat sink that is sized to be in thermal communication with all of the heat-generating components 160, 162, 164, and 166, or the circuit board 120 or both. Portions of the closed circulation path 131, as shown in FIG. 1, are disposed within the heat sinks 140, 142, 144, and 146, however in an alternative embodiment, the closed circulation path 131 of the liquid cooling system 130 can be disposed on the heat sinks or otherwise contact the surface of heat sinks 140, 142, 144, and 146.

The flow of the liquid cooling medium through the closed circulation path 131 can initiate from within the impeller housing 136 through conduit portion 150 and into heat sink 140, through conduit portion 152 through heat sink 142, through conduit portion 154, through heat sink 144, through conduit portion 156 to heat sink 146, through conduit portion 158 and back to impeller housing 136. The motor 132 drives the impeller 134 to rotate which forces the flow of liquid cooling medium through the impeller housing 136 and through the conduit 148.

In an alternative embodiment, the liquid cooling medium can flow in the opposite direction, for example, from the impeller 134 through conduit portion 158 to heat sink 146, and so on through conduit portions 156, 154, 152, and 150 which connect to heat sinks 144, 142 and 140, respectively. Regardless of the path of flow, the liquid cooling fluid absorbs heat produced by heat-generating components 160, 162, 164, 166 and the heat diffuses to the plurality of the heat sinks which radiate the heat from their surfaces. While flowing through the closed circulation path 131 the liquid cooling medium releases heat, and can be air cooled as it passes through conduit 148 and before being supplied back into the impeller housing 136. This cooling cycle is repeated.

The motor 132 is external to the closed circulation path and does not come into contact with the liquid cooling medium that flows within the closed circulation path 131. In this configuration the motor 132 can be removed from the liquid cooling system for repair or replacement without disturbing the liquid cooling medium, as will be further described. In this respect, the integrity of the closed circulation path 131 is maintained while decoupling the motor 132, thereby advantageously preventing a leak of the liquid cooling medium from the closed circulation path 131 while the motor 132 is decoupled therefrom.

The heat sinks 140 142, 144, and 146, are in thermal communication with heat-generating components (shown in phantom) 160, 162, 164, and 166, respectively. The “heat-generating component” as used herein describes one or more components that produce heat during operation. An electronic module, for example, may contain, but is not limited to, a semi-conductor package, one or more microprocessors, application specific integrated circuits (ASIC), analog circuits, digital circuits, programmed logic devices, memory devices, chips, for example. An electronic module that includes one or more microprocessors may also be referred to, for example, as a processor module.

FIG. 2 is a cross-sectional view of the electronic system 100 of FIG. 1 taken along lines 2-2. Heat-generating component 166 is shown attached to a connector 202 which is received by receptor 204 to make electrical connection to the printed circuit board 120. The heat-generating component can be connected to the circuit board 120 by a connector 202 that may be a pin connector and receptor 204 may be a pin receptor, for example. Alternatively, the connection between the heat-generating component 166 and printed circuit board 120 may be fixed, such as, for example, by a soldered connection, such as a ball grid array. Other types of connectors may also be used. The heat-generating component 166 can also be physically connected to the circuit board 120 by an adhesive or a combination of a connector and an adhesive.

Referring back to FIG. 1 the heat-generating component 166 is disposed between the circuit board 120 and the heat sink 146, however, in an alternative embodiment, the circuit board 120 can be disposed between the heat- generating component 166 and the heat sink 146. For example, the heat sink 146 can be located along the surface of the circuit board 120 that is opposite to the surface on which the heat-generating component 166 is mounted. In the embodiments described the liquid cooling system can transfer heat away from the heat-generating components 160, 162, 164, and 166 and the circuit board 120. The liquid cooling system 130 is in thermal communication with the heat-generating components, for example heat-generating component 166, and is also in thermal communication with the circuit board 120.

Heat sink 146 can have a top portion 208 and a bottom portion 210 that are connected by a plurality of securing devices, for example, securing devices 220, 222. Removal of the top portion 208 of heat sink 146 can allow for easy access of the conduit 148, for example conduit portion 170. Referring to FIGS. 1 and 2, conduit portion 170 is shaped, for example in a serpentine configuration, such that the flow of liquid cooling medium makes several passes along the surface of heat sink 146 to improve heat transfer from the liquid cooling medium to the heat sink 146.

In another embodiment of the invention, liquid cooling system 130 of the electronic system can further include a heat sink, for example heat sink 180, that extends radially from closed circulation path 131 of the liquid cooling system 130. Heat sink 180 can include a plurality of heat radiating plates 181 which can radiate heat from their surfaces to release heat from the liquid cooling medium. The additional surface area can result in greater heat transfer released from the electronic system. Heat sink 180 is shown along conduit portion 158, however, heat sink 180 can be located along one or more various locations along conduit 148.

Heat sinks 140, 142, 144, and 146, and 180 can be made of one of many thermally conductive materials, for example, materials that contain at least one of aluminum, copper, and graphite, which have a desirable heat transfer coefficient.

The conduit 148 for transporting the liquid cooling medium can be made of a thermally conductive material, for example copper, which has a desirable heat transfer coefficient and is corrosion resistant. The conduit 148 can also be made of a polymer, such as, a thermoplastic or thermoset polymer that has a desirable heat transfer coefficient, for example a silicone-based compound. It should be understood, however, that the conduit does not need to made of a thermally conductive material and many other materials may be used.

The liquid cooling medium can be any one of a variety of liquids including, but not limited to, water, and ethylene glycol, for example. In one embodiment, the liquid cooling medium has a specific heat that is much greater than air.

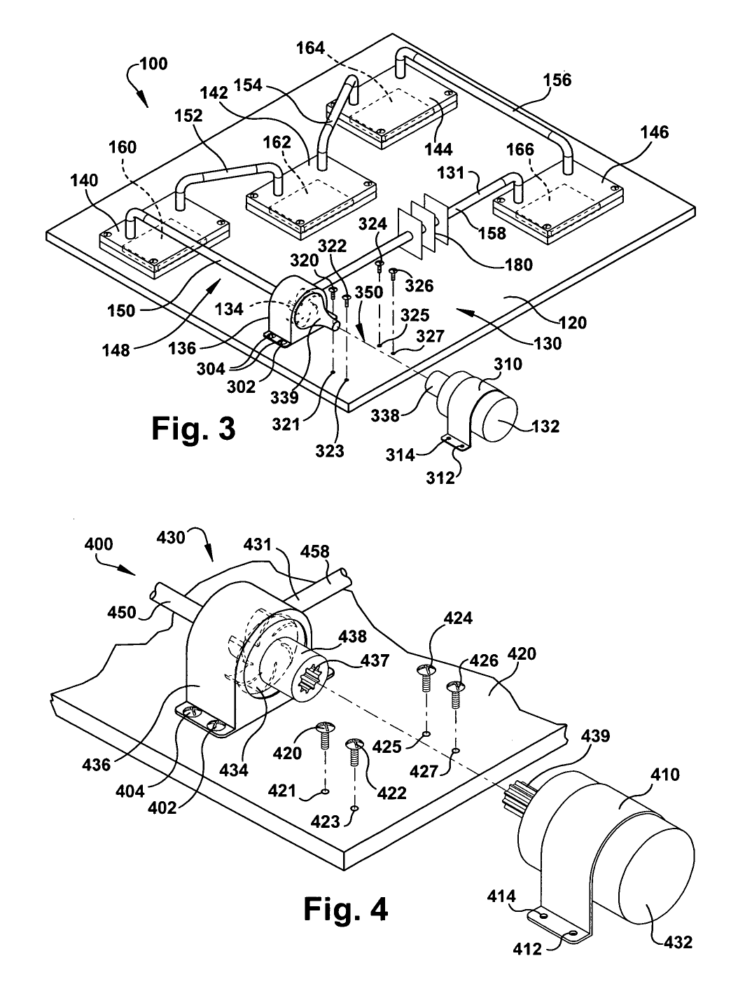

FIG. 3 is a perspective view of electronic system 100 of FIG. 1 showing the motor disassembled or removed from the liquid cooling system 130, according to an embodiment of the invention. The impeller 134 remains at least partially disposed within the closed circulation path 131 and the motor 132 is external to the closed circulation path 131.

In one embodiment of the invention, impeller 134 is driven by motor 132 in a contactless driving arrangement. As shown in FIGS. 1 and 3 the impeller 134 is magnetically-driven by the motor 132, for example. The motor 132 can include a rotary bearing 338 which slides around a driving shaft 339 of the impeller 134 to magnetically rotate the impeller 134. The rotation of the impeller 134 draws the liquid cooling medium into the impeller housing 136 and then discharges the liquid cooling medium through the conduit 148, for example conduit portion 150, along the closed circulation path 131 and to the heat sinks 140,142, 144, and 146 as described above with respect to FIGS. 1 and 2.

Securing devices 320, 322, 324, 326, and support bracket 310 support the motor 132 when it is connected to the printed circuit board 120 (FIG. 1) during operation of the liquid cooling system 130. Securing devices can be inserted through tab openings 312, 314, of the support bracket 310 and through openings 321, 323, 325, and 327 of printed circuit board 120. Support bracket 310 and securing devices 320, 322, 324 and 326, can engage the printed circuit board 120 directly, or to mounting hardware (not shown) which can be attached to the printed circuit board 120. Securing devices may be threaded to engage threads of the mounting hardware or they may be snap-fitted into a mating component of the mounting hardware or circuit board 120.

Securing devices 320, 322, 324, 326, and support bracket 310 are shown disconnected from the circuit board 120 so that the motor 132 can be removed from the liquid cooling system 130 and also from the electronic system 100, whereas the impeller housing 136 remains connected to the liquid cooling system 130, and optionally, the printed circuit board 120 by securing devices 302, 304. Once the motor 132 is decoupled from the impeller 134, the motor 132 can be pulled away from the impeller 134 along the axis of connection 350 while the closed circulation path 131 of the liquid cooling system 130 remains closed. This arrangement facilitates easy repair or replacement of the motor 132, or a motor component, without breaking the closed circulation path of the liquid cooling system 130.

In one embodiment the method for disassembling a liquid cooling system 131 in electronic system 100 comprises decoupling the motor 132 from the closed circulation path 131 containing liquid cooling medium. The motor 132 can be disconnected by unfastening the securing devices, such as for example, securing devices 320, 322, 324, and 326 and pulling the rotary bearing 338 away from the driving shaft 339 of the impeller 134, for example, such that magnetic attraction is dissipated.

FIG. 4 is a perspective view of electronic system 400 showing motor 432 disassembled or removed from the liquid cooling system 430, according to another embodiment of the invention. The liquid cooling system 430 of electronic system 400 includes closed circulation path 431, motor 432 and impeller 434 disposed inside housing 436.

Impeller 434 is driven by motor 432 in a mechanical driving arrangement. In one embodiment, the impeller housing 436 can include a shaft 438 that protrudes therefrom having a spline opening 437, for example an opening having protrusions are arrayed in the circumferential direction and extended in the radial direction. The spline opening 437 of shaft 439 can mate with or receive spline shaft 439 of the motor to mechanically rotate the impeller 434 to circulate the liquid cooling medium within the closed cooling path 431 of the liquid cooling system 430. The rotation of the impeller 434 driven by motor 432 draws the liquid cooling medium from within conduit, such as conduit portion 450 and into the impeller housing 436 and then discharges the liquid cooling medium through the conduit, for example conduit portion 458, and along the closed circulation path 431 to the heat sinks (not shown) along the same or similar alternative circulation paths as described above with respect to FIGS. 1 and 2.

One skilled in the art will recognize several alternative mechanisms are available for rotating the impeller 434. The impeller 434 may be driven directly from a motor 432 as shown. In an alternative embodiment, a motor 432 may drive a pulley arrangement or a gear arrangement formed on or attached to the impeller 434. For example, the impeller 434 may include a central axle (not shown) where one end of the axle is attached to a pulley wheel which is driven by a belt from a drive pulley attached to motor 432.

Securing devices 420, 422, 424, 426, and support bracket 410 are shown disconnected from the circuit board 120 so that the motor 432 can be removed from the liquid cooling system 130 and electronic system 100, whereas the impeller housing 436 remains connected to the liquid cooling system 130 and the printed circuit board 420 by securing devices 402, 404. Once the motor 432 is decoupled from the impeller 434, the motor 432 can be pulled away from the impeller 434 while the closed circulation path 431 of the liquid cooling system 430 remains closed.

A method for disassembling liquid cooling system 430 of electronic system 400 includes decoupling the motor 432 from the closed circulation path 431 containing liquid cooling medium. The motor 432 can be disconnected by unfastening the securing devices, for example, securing devices 420, 422, 426, 428, from openings 421, 423, 425, 427, and then pulling the spline shaft 439 out of the spline opening 437. The motor 432 can then be repaired or replaced without accessing the closed circulation path 431 and thus avoiding possible damage of components within the electronic system 400 caused by liquid cooling medium. Specifically, the integrity of the closed circulation path 431 is maintained while decoupling the motor 436, thereby preventing a leak of the liquid cooling medium from the closed circulation path 431 while the motor 436 is decoupled therefrom.

In the embodiments of the invention shown and described above, for example in electronic system 100 (FIG. 1), the motor 132 and the impeller 134 are attached to the circuit board 120 inside enclosure 102, however the enclosure 102 is not necessary. In an alternative embodiment the heat sinks 140, 142, 144, and 146 of the liquid cooling system 130 can be located on the circuit board 120, 420 and motor 132, 432, and the impeller 134, 434, can be remote from the circuit board 120.

In another embodiment the motor 132 and the impeller 134 are external to enclosure 102 (FIG. 1). In such arrangement the motor 132 and the impeller 134 can be located in a separate enclosure (not shown) and the closed circulation path 131 (FIG. 1) can extend between two or more enclosures.

Although the invention is shown and described with respect to certain embodiments, it is obvious that equivalents and modifications will occur to others skilled in the art upon the reading and understanding of the specification. The present invention includes all such equivalents and modifications, and is limited only by the scope of the claims.

What is claimed is:

1. A system comprising:
a closed circulation path comprising liquid cooling medium;
an impeller at least partially disposed within the closed circulation path;
a motor coupled to the closed circulation path, the motor being removable from the closed circulation path; and
an electronic system in thermal communication with the closed circulation path, wherein an integrity of the closed circulation path is maintained when the motor is removed from the closed circulation path, thereby preventing a leak of the liquid cooling medium from the closed circulation path while the motor is decoupled therefrom.

2. The system of claim 1, wherein the electronic system further comprises a heat generating component; and
the system further comprises a heat sink in thermal communication with the heat generating component and the closed circulation path.

3. The system of claim 1, wherein the motor is magnetically coupled to an impeller associated with the closed circulation path.

4. The system of claim 1, wherein the motor is mechanically coupled to an impeller associated with the closed circulation path.

5. The system of claim 2, wherein at least a portion of the closed circulation path contacts the heat sink.

6. The system of claim 5, wherein at least a portion of the closed circulation path is disposed within the heat sink.

7. The system of claim 1, wherein the electronic system is located in an enclosure and at least a portion of the closed circulation path is internal to the enclosure.

8. The system of claim 7, wherein the motor and impeller are external to the enclosure.

9. The system of claim 1, wherein the electronic system further comprises an integrated circuit in thermal communication with the closed circulation path.

10. The system of claim 1, wherein the electronic system comprises a heat-generating component attached to a circuit board.

11. The system of claim 10, wherein the heat-generating component is disposed between the circuit board and a heat sink.

12. The system of claim 10, wherein the circuit board is disposed between the heat-generating component and the heat sink.

13. The system of claim 10, wherein the motor and an impeller are attached to the circuit board.

14. The system of claim 9, further comprising an enclosure the electronic system being located internal to the enclosure.

15. The system of claim 14, wherein the closed circulation path is internal to the enclosure.

16. The system of claim 14, wherein the motor and impeller are external to the enclosure.

17. An system, comprising:
a closed circulation path comprising a liquid cooling medium;
an electronic system in thermal communication with the closed circulation path;
means for circulating the liquid cooling medium through the closed circulation path;
means for driving the means for circulating the liquid cooling medium through the closed circulation path; and
wherein the means for driving may be removed from the liquid cooling system while the closed circulation path remains closed.

18. The system of claim 17, wherein the means for driving comprises a motor.

19. The system of claim 17, wherein the means for circulating the liquid cooling medium comprises an impeller.

20. The system of claim 18, wherein the means for circulating the liquid cooling medium comprises an impeller.

21. The system of claim 20, wherein the motor is magnetically coupled to the impeller.

22. The system of claim 20, wherein the motor is mechanically coupled to the impeller.

23. A method for disassembling a liquid cooling system of an electronic system comprising:
decoupling the motor from a closed circulation path containing liquid cooling medium, the closed circulation path being thermally coupled to the electronic system; and
maintaining an integrity of the closed circulation path while decoupling the motor, thereby preventing a leak of the liquid cooling medium from the closed circulation path while the motor is decoupled therefrom.

24. The method of claim 23, wherein the motor is magnetically decoupled from an impeller disposed within the liquid cooling system.

25. The method of claim 23, wherein the motor is mechanically decoupled from an impeller disposed within the liquid cooling system.
